(19) United States
(12) Patent Application Publication
(10) Pub. No.: US 2020/0033414 A1
(43) Pub. Date: Jan. 30, 2020

(54) BATTERY INFORMATION PROCESSING SYSTEM, METHOD OF ESTIMATING CAPACITY OF SECONDARY BATTERY, AND BATTERY ASSEMBLY AND METHOD OF MANUFACTURING BATTERY ASSEMBLY

(71) Applicant: TOYOTA JIDOSHA KABUSHIKI KAISHA, Toyota-shi (JP)

(72) Inventors: Junta IZUMI, Nagoya-shi (JP); Masahiko MITSUI, Toyota-shi (JP); Juni YASOSHIMA, Toyota-shi (JP); Kotaro SHIBUYA, Nagoya-shi (JP)

(73) Assignee: TOYOTA JIDOSHA KABUSHIKI KAISHA, Toyota-shi (JP)

(21) Appl. No.: 16/511,212

(22) Filed: Jul. 15, 2019

(30) Foreign Application Priority Data
Jul. 30, 2018 (JP) 2018-142797

(51) Int. Cl. G01R 31/385; G01R 31/389; G01R 31/36; G06N 3/02

(52) U.S. Cl. CPC G01R 31/385; G06N 3/02; G01R 31/3644; G01R 31/389

(57) ABSTRACT

A battery information processing system processes information for estimating a full charge capacity of a module. The battery information processing system includes a storage device configured to store a trained neural network model and an analysis device configured to estimate a full charge capacity of a secondary battery from a result of measurement of an AC impedance of the module by using the trained neural network model. The trained neural network model includes an input layer given a numeric value for each pixel of an estimation image in which a Nyquist plot representing the result of measurement of the AC impedance of the module is drawn in a region consisting of a predetermined number of pixels.

This nonprovisional application is based on Japanese Patent Application No. 2018-142797 filed with the Japan Patent Office on Jul. 30, 2018, the entire contents of which are hereby incorporated by reference.

### BACKGROUND

### Field

The present disclosure relates to a battery information processing system, a method of estimating a capacity of a secondary battery, as well as a battery assembly and a method of manufacturing the battery assembly, and more particularly to an information processing technique for estimating a full charge capacity of a secondary battery.

### Description of the Background Art

Electrically powered vehicles incorporating battery assemblies (hybrid vehicles or electric vehicles) have increasingly been used in recent years. Battery assemblies mounted on vehicles are collected on the occasion of replacement purchase of these electrically powered vehicles. The number of collected battery assemblies is expected to rapidly increase in the future.

In general, a battery assembly may deteriorate with lapse of time or with repeated charging and discharging, and a degree of progress of deterioration is different for each collected battery assembly. Therefore, it has been required to evaluate characteristics (a full charge capacity or the like) reflecting a degree of progress of deterioration of each of the collected battery assemblies and to recycle the battery assemblies in accordance with results of evaluation.

An alternating-current (AC) impedance measurement method has been known as an approach to evaluation of characteristics of a secondary battery. For example, Japanese Patent Laying-Open No. 2003-317810 discloses a method of determining whether or not minor short-circuiting has occurred in a secondary battery based on a reaction resistance value of the secondary battery obtained by the AC impedance measurement method.

### SUMMARY

A full charge capacity of a secondary battery represents a particularly important characteristic among characteristics reflecting a degree of progress of deterioration of the secondary battery. For example, in a battery assembly to be mounted on a vehicle, a full charge capacity of the battery assembly greatly affects a traveling distance of an electrically powered vehicle.

In general, a battery assembly to be mounted on a vehicle includes a plurality of (for example, several to more than ten) modules and each of the plurality of modules includes a plurality of (for example, several ten) cells. In estimating a full charge capacity of such a battery assembly, a procedure as below may be performed. A plurality of modules are taken out of a collected battery assembly and an AC impedance is measured for each module. Then, the full charge capacity of the module is estimated based on a result of measurement of the AC impedance of each module. In addition, whether or not the module is recyclable or a manner of recycle (an application) may be determined based on a result of estimation of the full charge capacity of the module.

In the AC impedance measurement method, an AC signal at a frequency within a prescribed range is successively applied to a secondary battery and a response signal from the secondary battery at that time is measured. A real number component and an imaginary number component of an impedance of the secondary battery are calculated from the applied AC signal (an application signal) and the measured response signal, and results of calculation are discretely plotted on a complex plane. This complex impedance plot is also called a Nyquist plot.

By analyzing the Nyquist plot, the full charge capacity of the secondary battery can be estimated. Though details will be described later, various approaches are possible as an approach to analysis of a Nyquist plot, and a possible approach to estimation of a full charge capacity of a secondary battery as accurate as possible is desirably adopted.

The present disclosure was made to solve the problems above, and an object thereof is to improve accuracy in estimation of a full charge capacity of a secondary battery in a battery information system or a method of estimating a capacity of a secondary battery. Another object of the present disclosure is to provide a battery assembly including a battery of which full charge capacity has highly accurately been estimated and a method of manufacturing the same.

(1) A battery information processing system according to one aspect of the present disclosure processes information for estimating a full charge capacity of a secondary battery. The battery information processing system includes a storage device configured to store a trained neural network model and an estimation device configured to estimate a full charge capacity of the secondary battery from a result of measurement of an AC impedance of the secondary battery by using the trained neural network model. The trained neural network model includes an input layer given a numeric value for each pixel of an image in which a Nyquist plot is drawn in a region consisting of a predetermined number of pixels, the Nyquist plot representing the result of measurement of the AC impedance of the secondary battery.

(2) The number of pixels in the region is greater than a sum of the number of real number components and the number of imaginary number components both representing the result of measurement of the AC impedance of the secondary battery.

(3) The result of measurement of the AC impedance of the secondary battery includes a result of measurement of the AC impedance when a frequency of an applied AC signal is within a frequency range not lower than 100 mHz and not higher than 1 kHz.

According to the features in (1) to (3), an image (numeric data for each pixel in the image) in which a Nyquist plot is drawn in a region consisting of a predetermined number of pixels is given to the input layer as input information. As compared with an example in which numeric data of a result of measurement of an AC impedance of a module is used as it is (Comparative Example 2 which will be described later), an amount of input information given to the input layer significantly increases. This means that input of information which can express a difference in full charge capacity between one secondary battery and another secondary battery increases in advance training of a neural network so that high-precision training of the neural network can be realized (details of which will be described later). Therefore, accuracy in estimation of a full charge capacity of a secondary battery can be improved.

(4) A battery assembly according to another aspect of the present disclosure includes a plurality of the secondary batteries of which full charge capacity has been estimated by the battery information processing system described above.

According to the feature in (4), a battery assembly including a secondary battery of which full charge capacity has highly accurately been estimated by the battery information system can be provided.

(5) A method of estimating a capacity of a secondary battery according to yet another aspect of the present disclosure includes obtaining a result of measurement of an AC impedance of the secondary battery and estimating a full charge capacity of the secondary battery from the result of measurement of the AC impedance of the secondary battery by using a trained neural network model. The trained neural network model includes an input layer given a numeric value for each pixel of an image in which a Nyquist plot is drawn in a region consisting of a predetermined number of pixels, the Nyquist plot representing the result of measurement of the AC impedance of the secondary battery.

According to the method in (5), as in the features in (1), accuracy in estimation of a full charge capacity of a secondary battery can be improved.

(6) A method of manufacturing a battery assembly according to still another aspect of the present disclosure includes obtaining a result of measurement of an AC impedance of a secondary battery, estimating a full charge capacity of the secondary battery from the result of measurement of the AC impedance of the secondary battery by using a trained neural network model, and manufacturing a battery assembly from a plurality of secondary batteries of which full charge capacity has been estimated in the estimating a full charge capacity. The trained neural network model includes an input layer given a numeric value for each pixel of an image in which a Nyquist plot is drawn in a region consisting of a predetermined number of pixels, the Nyquist plot representing the result of measurement of the AC impedance of the secondary battery.

According to the method in (6), as in the feature in (4), a battery assembly including a secondary battery of which full charge capacity has highly accurately been estimated can be manufactured.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram showing one manner of distribution from collection to manufacturing and sales of battery assemblies in the present embodiment.

FIG. 2 is a flowchart showing a flow of processing in a battery distribution model shown in FIG. 1.

FIG. 3 is a diagram showing an exemplary configuration of a battery management system applied to the battery distribution model shown in FIG. 1.

FIG. 4 is a diagram showing a configuration of a battery information system.

FIG. 5 is a flowchart showing processing for estimating a capacity of a module in Comparative Example 1.

FIG. 6 is a diagram showing one example of a Nyquist plot of a result of measurement of an AC impedance of a module.

FIG. 7 is a diagram showing an equivalent circuit model of a module in Comparative Example 1.

FIG. 8 is a diagram showing an impedance curve obtained by fitting processing of the result of measurement of the AC impedance of the module.

FIG. 9 is a diagram for illustrating one example of accuracy in estimation of a capacity of a module in Comparative Example 1.

FIG. 10 is a conceptual diagram for illustrating training of a neural network model in Comparative Example 2.

FIG. 11 is a diagram for illustrating one example of accuracy in estimation of a capacity of a module in Comparative Example 2.

FIG. 12 is a conceptual diagram for illustrating machine learning by a neural network model in the present embodiment.

FIG. 13 is a flowchart showing training of the neural network model in the present embodiment.

FIG. 14 is a flowchart showing processing for estimating a capacity of a module in the present embodiment.

FIG. 15 is a diagram for illustrating one example of accuracy in estimation of a capacity of a module in the present embodiment.

### DESCRIPTION OF THE PREFERRED EMBODIMENTS

An embodiment of the present disclosure will be described below in detail with reference to the drawings. The same or corresponding elements in the drawings have the same reference characters allotted and description thereof will not be repeated.

In the present disclosure, a battery assembly includes a plurality of modules (or also called blocks). The plurality of modules may be connected in series or in parallel. Each of the plurality of modules includes a plurality of cells (unit cells) connected in series.

“Manufacturing” of a battery assembly in the present disclosure means manufacturing of a battery assembly by replacing at least one of a plurality of modules included in a battery assembly with other modules (replacement modules). Though the replacement module is basically a recyclable module taken out of a collected battery assembly, it may be a new module.

In general, “recycle” of a battery assembly is broadly categorized into reuse, rebuild, and resource recycle. In the case of reuse, collected battery assemblies are subjected to necessary shipment inspection and shipped as they are as reuse products. In the case of rebuild, collected battery assemblies are once disassembled to modules (which may be cells). Then, among the disassembled modules, modules which can be used after reconditioning (which may be modules which can be used as they are) are combined to manufacture a new battery assembly. Newly manufactured battery assemblies are subjected to shipment inspection and shipped as rebuilt products. In resource recycle, renewable materials are taken out of each cell and hence collected battery assemblies are not used as other battery assemblies.

In the embodiment described below, a battery assembly collected from a vehicle is once disassembled into modules and a performance test is conducted for each module. A battery assembly is manufactured from modules determined as being recyclable as a result of the performance test. Therefore, a recyclable module means a rebuildable module below. Depending on a configuration of a battery assembly, however, a battery assembly as it is can also be subjected to the performance test without being disassembled into modules. “Recycle” in such a case may encompass both of reuse and rebuild.

In the present embodiment, each cell is implemented by a nickel metal hydride battery. More specifically, a positive electrode is composed of nickel hydroxide (Ni(OH)₂) to which a cobalt oxide additive is added. A negative electrode is composed of a hydrogen storage alloy (based on MnNi5 which represents a nickel-based alloy). An electrolyte solution is composed of potassium hydroxide (KOH). These, however, are merely by way of example of a specific cell configuration, and a cell configuration to which the present disclosure is applicable is not limited thereto.

### Embodiment

<Battery Distribution Model>

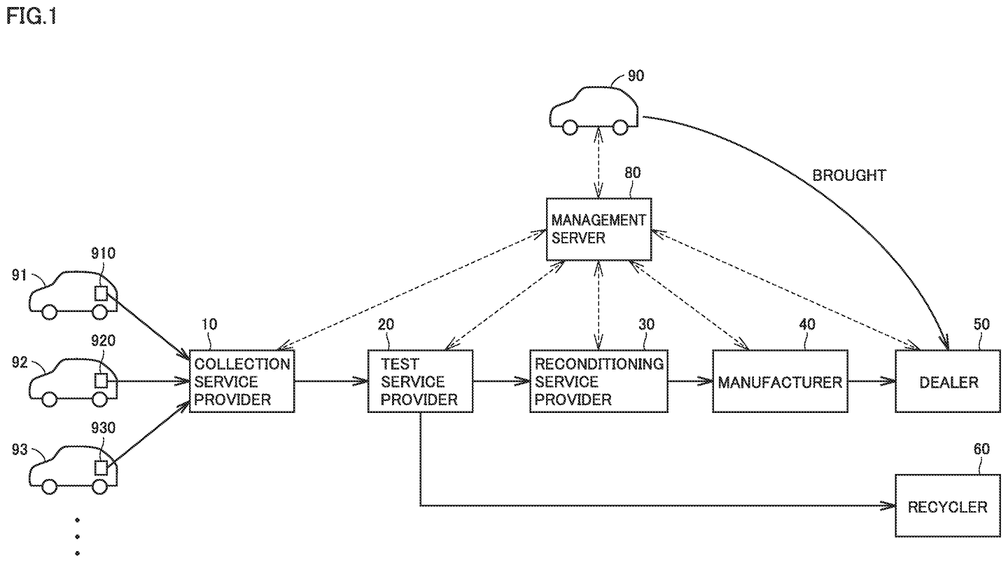

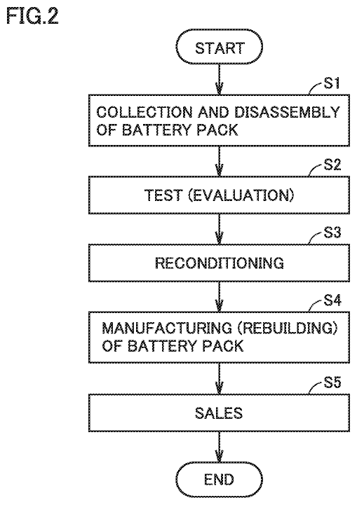

FIG. 1 is a diagram showing one manner of distribution from collection to manufacturing and sales of battery assemblies in the present embodiment. A manner of distribution shown in FIG. 1 is referred to as a “battery distribution model” below. FIG. 2 is a flowchart showing a flow of processing in the battery distribution model shown in FIG. 1.

Referring to FIGS. 1 and 2, in the battery distribution model, used battery assemblies are collected from a plurality of vehicles each incorporating battery assemblies, and battery assemblies are manufactured from recyclable modules included in the collected battery assemblies and then sold. A battery assembly mounted on a vehicle 90 of a certain user is replaced.

A collection service provider 10 collects used battery assemblies from vehicles 91 to 93. Battery assemblies 910 to 930 are mounted on vehicles 91 to 93, respectively. Though FIG. 1 shows only three vehicles due to space restriction, battery assemblies are actually collected from a larger number of vehicles. Collection service provider 10 disassembles the collected battery assemblies and takes out a plurality of modules from the battery assemblies (step Si, hereinafter the step being abbreviated as “S”).

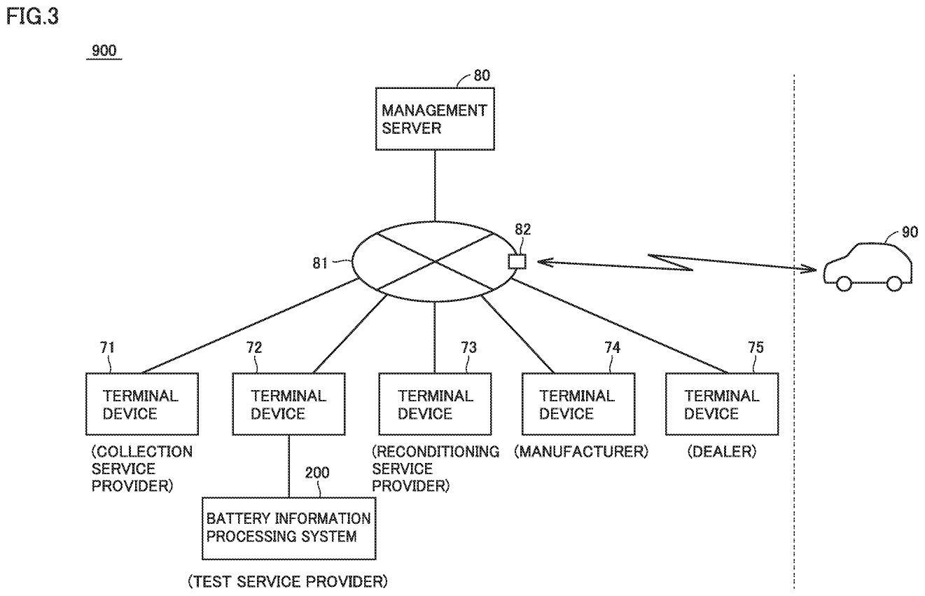

In this battery distribution model, identification information (ID) for identifying a module is provided for each module, and a management server 80 manages information on each module. Therefore, collection service provider 10 transmits an ID of each module taken out of a battery assembly to management server 80 through a terminal device 71 (see FIG. 3).

A test service provider 20 tests performance of each module collected by collection service provider 10 (S2). Specifically, test service provider 20 tests characteristics of the collected module. For example, test service provider 20 tests such electrical characteristics as a full charge capacity, a resistance value, an open circuit voltage (OCV), and a state of charge (SOC). Then, test service provider 20 classifies the modules into recyclable modules and non-recyclable modules based on results of the test, passes the recyclable modules to a reconditioning service provider 30 and the non-recyclable modules to a recycler 60. A test result of each module is transmitted to management server 80 through a terminal device 72 (see FIG. 3) of test service provider 20.

Reconditioning service provider 30 performs a process for reconditioning the module determined as recyclable by test service provider 20 (S3). By way of example, reconditioning service provider 30 restores a full charge capacity of the module by charging the module to an overcharged state. For a module determined as less in lowering in performance in the test by test service provider 20, the reconditioning process performed by reconditioning service provider 30 may be skipped. A result of reconditioning of each module is transmitted to management server 80 through a terminal device 73 (see FIG. 3) of reconditioning service provider 30.

A manufacturer 40 manufactures a battery assembly from modules reconditioned by reconditioning service provider 30 (S4). In the present embodiment, information (assembly information) for manufacturing a battery assembly is generated by management server 80 and transmitted to a terminal device 74 (see FIG. 3) of manufacturer 40. Manufacturer 40 manufactures (rebuilds) a battery assembly of vehicle 90 by replacing a module included in the battery assembly of vehicle 90 in accordance with the assembly information.

A dealer 50 sells the battery assembly manufactured by manufacturer 40 for vehicle use or for stationary use in a house or the like (S5). In the present embodiment, vehicle 90 is brought to dealer 50 and dealer 50 replaces the battery assembly of vehicle 90 with a reuse product or a rebuilt product manufactured by manufacturer 40.

Recycler 60 disassembles modules determined as being non-recyclable by test service provider 20 for reclamation for use as new cells or as source materials for other products.

Though collection service provider 10, test service provider 20, reconditioning service provider 30, manufacturer 40, and dealer 50 are service providers different from one another in FIG. 1, classification of the service providers is not limited as such. For example, a single service provider may serve as test service provider 20 and reconditioning service provider 30. Alternatively, collection service provider 10 may be divided into a service provider which collects battery assemblies and a service provider which disassembles collected battery assemblies. Locations of each service provider and each dealer are not particularly limited. Locations of each service provider and each dealer may be different or a plurality of service providers or dealers may be located at the same place.

FIG. 3 is a diagram showing an exemplary configuration of a battery management system applied to the battery distribution model shown in FIG. 1. Referring to FIG. 3, a battery management system 100 includes terminal devices 71 to 75, management server 80, a communication network 81, and a base station 82.

Terminal device 71 is a terminal device of collection service provider 10. Terminal device 72 is a terminal device of test service provider 20. Terminal device 73 is a terminal device of reconditioning service provider 30. Terminal device 74 is a terminal device of manufacturer 40. Terminal device 75 is a terminal device of dealer 50.

Management server 80 and terminal devices 71 to 75 are configured to communicate with one another through communication network 81 such as the Internet or telephone lines. Base station 82 on communication network 81 is configured to be able to transmit and receive information to and from vehicle 90 through wireless communication.

In test service provider 20, a battery information system (which may be abbreviated as a “processing system” below) 200 for measuring an AC impedance of each module and determining a manner of recycle (rebuild or resource recycle) of the module based on a result of measurement is provided. The manner of recycle of the module determined by processing system 200 is transmitted to management server 80, for example, through terminal device 72.

A full charge capacity of a certain module (which is denoted as a “module M” below) among a plurality of modules included in battery assembly 910 taken out of vehicle 91 is estimated by processing system 200 below. A manner of recycle of module M is further determined based on a result of estimation of the full charge capacity of module M.

<Configuration of Battery Information System>

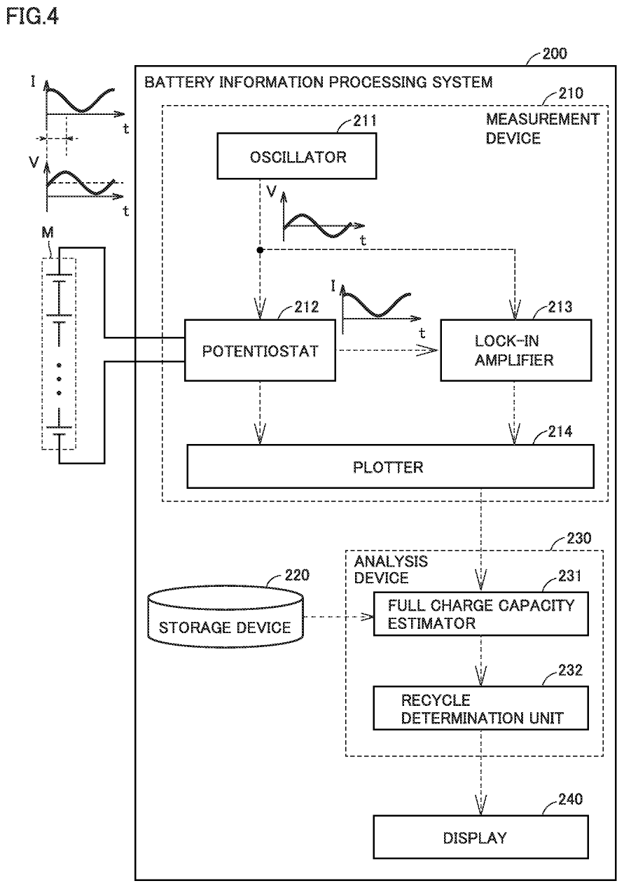

FIG. 4 is a diagram showing a configuration of processing system 200. Processing system 200 includes a measurement device 210, a storage device 220, an analysis device 230, and a display 240. These devices may be configured as devices independent of one another or as a single device.

Measurement device 210 measures an AC impedance of module M and outputs a Nyquist plot representing a result of measurement to analysis device 230. More specifically, measurement device 210 includes an oscillator 211, a potentiostat 212, a lock-in amplifier 213, and a plotter 214.

Oscillator 211 outputs sinusoidal waves identical in phase to potentiostat 212 and lock-in amplifier 213.

Potentiostat 212 generates an application signal by superimposing a prescribed direct-current (DC) voltage on an AC voltage (for example, a voltage at an amplitude around 10 mV) identical in phase to sinusoidal waves from oscillator 211 and applies the generated application signal to module M. Then, potentiostat 212 detects a current which flows through module M and outputs a result of detection to lock-in amplifier 213 as a response signal from module M. Potentiostat 212 outputs the application signal and the response signal to plotter 214.

Lock-in amplifier 213 compares a phase of the sinusoidal waves received from oscillator 211 with a phase of the response signal detected by potentiostat 212 and outputs a result of comparison (a phase difference between the sinusoidal waves and the response signal) to plotter 214.

Plotter 214 plots a result of measurement of an AC impedance of module M on a complex plane based on a signal from potentiostat 212 (a signal indicating an amplitude ratio between the application signal and the response signal) and a signal from lock-in amplifier 213 (a signal indicating a phase difference between the application signal and the response signal). More specifically, a frequency of sinusoidal waves output from oscillator 211 is swept in a prescribed frequency range and processing described previously is repeatedly performed by potentiostat 212 and lock-in amplifier 213. Thus, results of measurement of an AC impedance of module M for each frequency of sinusoidal waves are plotted on the complex plane. This plot is called a “Nyquist plot” (which may also be called a Cole-Cole plot). The Nyquist plot of module M is output to analysis device 230.

The configuration of measurement device 210 is not limited to the configuration shown in FIG. 4. For example, though description that an AC voltage is applied to module M and a current which flows through module M at that time is detected has been given, potentiostat 212 may detect a voltage response at the time of application of an AC current to module M. Measurement device 210 may include a frequency response analyzer (not shown) instead of lock-in amplifier 213.

An approach below can also be adopted as an approach to measurement of an AC impedance. Specifically, an application signal (one of a voltage signal and a current signal) including various frequency components within a prescribed frequency range is generated, and a response signal (the other of the voltage signal and the current signal) at the time of application of the application signal is detected. Each of the application signal and the response signal is subjected to fast Fourier transform (FFT) for frequency decomposition, to thereby calculate an AC impedance for each frequency. A Nyquist plot can be created also by such an approach.

Storage device 220 stores a trained (learned) neural network model for estimation of a full charge capacity of a module by analysis device 230. Storage device 220 trains the neural network model, updates a result of training, and outputs the result of training to analysis device 230 by being referred to by analysis device 230 in response to a request from analysis device 230.

Analysis device 230 is implemented, for example, by a microcomputer including a central processing unit (CPU), a memory, and an input/output port (none of which is shown). Specifically, analysis device 230 includes a full charge capacity estimator 231 and a recycle determination unit 232.

Full charge capacity estimator 231 estimates a full charge capacity of module M by analyzing a Nyquist plot of module M obtained by measurement device 210. This processing is referred to as “capacity estimation processing” below. Capacity estimation processing by analysis device 230 will be described in detail later.

Recycle determination unit 232 determines a manner of recycle of module M based on a result of estimation of the full charge capacity of module M. Recycle determination unit 232 may determine whether or not module M is recyclable. The full charge capacity of module M estimated by analysis device 230 and the manner of recycle determined by recycle determination unit 232 are output to display 240.

Display 240 is implemented, for example, by a liquid crystal display and shows a result of capacity estimation processing and a result of determination of the manner of recycle of module M by analysis device 230. The test service provider can thus know how module M should be processed.

Analysis device 230 corresponds to the “estimation device” according to the present disclosure. Recycle determination unit 232 is not a feature essential for estimation of a full charge capacity of module M in analysis device 230. Storage device 220 and analysis device 230 correspond to the “battery information system” according to the present disclosure.

<Capacity Estimation Processing in Comparative Example 1>

In succession, a flow of processing for estimating a capacity of module M will be described in detail. In capacity estimation processing, an AC impedance of module M is measured and a full charge capacity of module M is estimated by analyzing a result of measurement. In estimating the full charge capacity from the result of measurement of the AC impedance, various analysis approaches may be applied. In order to clarify a feature of capacity estimation processing in the present embodiment below, initially, capacity estimation processing in two comparative examples (Comparative Examples 1 and 2) will be described.

FIG. 5 is a flowchart showing processing for estimating a capacity of module M in Comparative Example 1. This flowchart is executed by processing system 200, for example, when the test service provider sets module M in processing system 200 and operates a not-shown operation portion (such as a start button).

For the sake of brevity of description, components (such as each constituent element included in measurement device 210 or analysis device 230) of processing system 200 as an entity to perform each type of processing are not particularly distinguished below and they are comprehensively denoted as “processing system 200.” Though each step is basically performed by software processing by processing system 200, it may partly or entirely be performed by hardware (an electric circuit) provided in processing system 200.

Referring to FIG. 5, in step S11, processing system 200 measures an AC impedance of module M and obtains a Nyquist plot from a result of measurement. Since the approach to measurement of an AC impedance has been described in detail in description of the configuration of measurement device 210 with reference to FIG. 4, description will not be repeated.

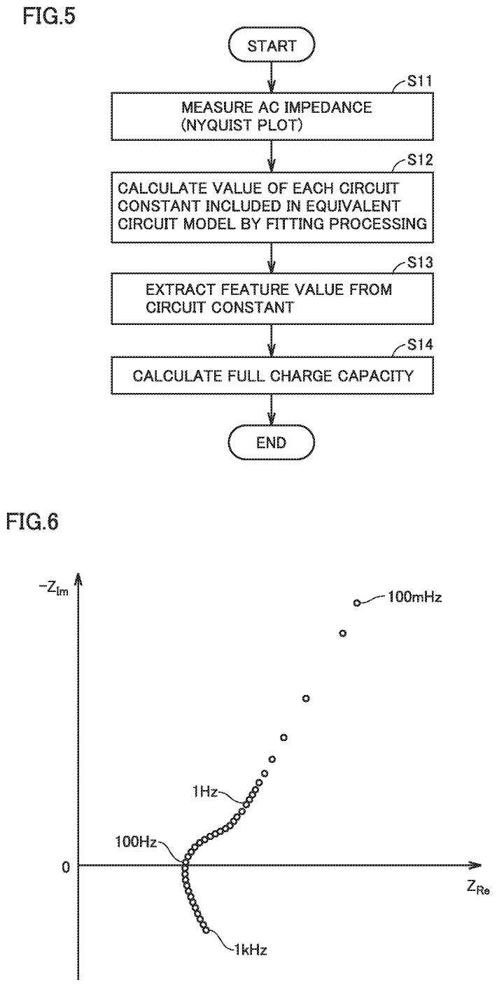

FIG. 6 is a diagram showing one example of a Nyquist plot of a result of measurement of an AC impedance of module M. In FIG. 6, the abscissa represents a real number component Z_{Re} of a complex impedance of module M and the ordinate represents an imaginary number component −Z_{Im} of the complex impedance of module M.

FIG. 6 shows one example of a result of measurement of an AC impedance when a frequency of an application signal is swept within a range from 100 mHz to 1 kHz. As shown in FIG. 6, in the Nyquist plot, a result of measurement of an AC impedance of module M in accordance with a frequency of the application signal is plotted on the complex plane as a discrete value. In Comparative Example 1, an equivalent circuit model representing frequency characteristics of an AC impedance of module M is constructed in advance based on results of evaluation or results of simulation of a large number of modules.

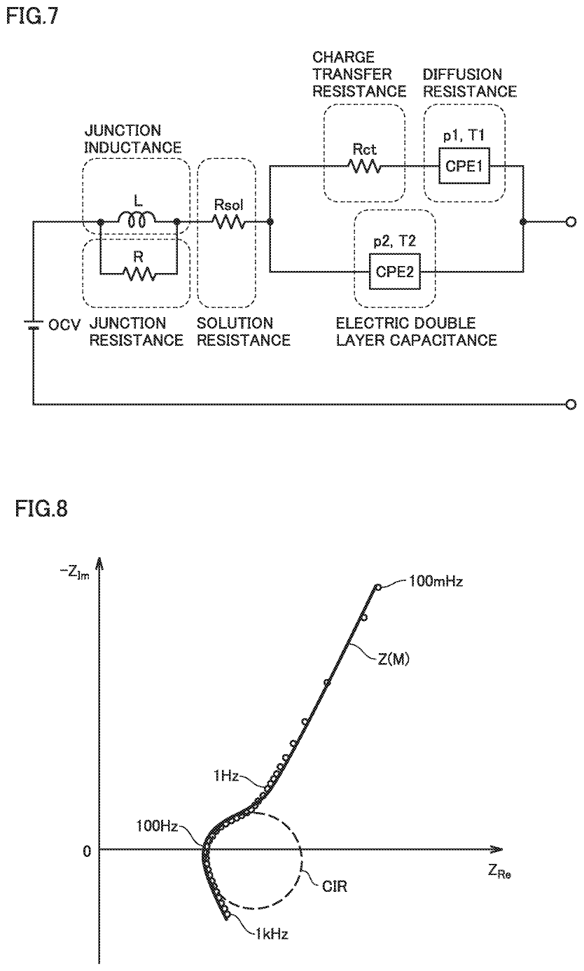

FIG. 7 is a diagram showing an equivalent circuit model of a module in Comparative Example 1. Referring to FIG. 7, an equivalent circuit model in Comparative Example 1 includes as circuit constants (model parameters), a junction inductance L, a junction resistance R, a solution resistance Rsol, a charge transfer resistance Rct, a diffusion resistance (denoted as CPE1), and an electric double layer capacitance (denoted as CPE2).

Junction inductance L refers to an inductance component in a portion of junction between cells included in a module (a portion of junction between the positive electrode and the negative electrode). Junction resistance R refers to a resistance component in the junction portion. Solution resistance Rsol refers to a resistance component of an electrolyte solution present between the positive electrode and the negative electrode. Charge transfer resistance Rct refers to a resistance component relating to transfer of charges (supply and reception of charges) at an electrode/electrolyte interface (surfaces of a positive electrode active material and a negative electrode active material). The diffusion resistance refers to a resistance component relating to diffusion of a charge transfer material in salt or an active material in the electrolyte solution. The electric double layer capacitance refers to a capacitance component of an electric double layer formed at an electrode/electrolyte solution interface. Each of these circuit constants results from combination of corresponding components in all cells in the module.

Junction inductance L and junction resistance R are connected in parallel to each other. Solution resistance Rsol is connected in series to a parallel circuit of junction inductance L and junction resistance R. Charge transfer resistance Rct and the diffusion resistance are connected in series to each other. A series circuit of charge transfer resistance Rct and the diffusion resistance and the electric double layer capacitance are connected in parallel to each other. A combined circuit including junction inductance L, junction resistance R, and solution resistance Rsol and a combined circuit including charge transfer resistance Rct, the diffusion resistance, and the electric double layer capacitance are connected in series to each other.

Each of the diffusion resistance and the electric double layer capacitance of the module is expressed by a non-linear element called a constant phase element (CPE). Specifically, an impedance Z_{CPE1} corresponding to the diffusion resistance is expressed as shown in an expression (1) below with a CPE index p1 and a CPE constant T1. In the expression (1), an angular frequency of an AC signal applied to the module (application signal) is denoted as ω (ω=2πf).

Z_{CPE1}=1/{(jω)^{p1}×T1} (1)

Similarly, an impedance Z_{CPE2} corresponding to the electric double layer capacitance can also be expressed as shown in an expression (2) below with a CPE index p2 and a CPE constant T2.

Z_{CPE2}=1/{(jω)^{p2}×T2} (2)

A combined impedance of module M is expressed by a prescribed expression including eight circuit constants included in the equivalent circuit model. An expression which expresses a combined impedance of module M is referred to as an “impedance curve Z(M)” below.

Referring again to FIG. 5, in S12, processing system 200 performs fitting processing (curve regression) of an impedance curve Z so as to be best applied to the Nyquist plot (a measured value in S11) created by plotter 214. For example, the non-linear least squares method (LSQ) can be used as an approach to curve regression. Specifically, processing system 200 calculates, for each frequency of the application signal, a coordinate plotted (measured) at that frequency and a coordinate on impedance curve Z(M) corresponding to the frequency. Processing system 200 calculates a square of a distance (an error) between these coordinates for all frequencies of the application signal and totals the calculated values. Processing system 200 calculates a square sum of errors and adjusts values of the eight circuit constants included in the equivalent circuit model so as to minimize the square sum of the errors. Fitting processing by the non-linear least squares method is repeated until a prescribed convergence condition is satisfied (for example, a value representing a degree of fitting in fitting processing such as a chi-square value becomes lower than a criterion value). Consequently, when it is determined that the convergence condition is satisfied, impedance curve Z(M) is specified.

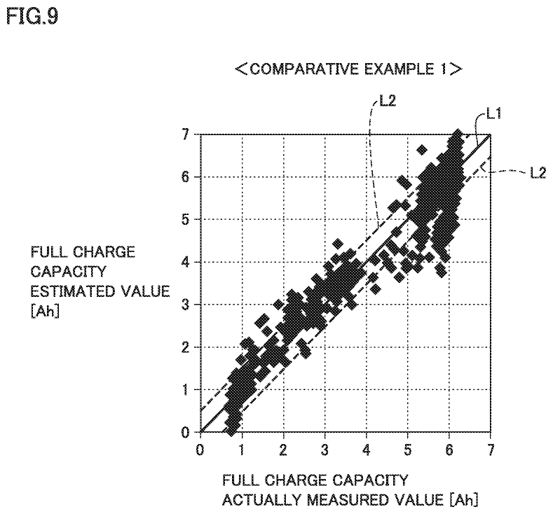

FIG. 8 is a diagram showing impedance curve Z(M) obtained by fitting processing of the result of measurement of the AC impedance of module M. FIG. 8 shows with a bold line, a curve representing impedance curve Z(M) specified by fitting processing. A fitting algorithm is not limited to the least squares method, and another algorithm such as a genetic algorithm (GA) can also be adopted.

Referring back to FIG. 5, in S13, processing system 200 extracts a feature value F(M) from the eight circuit constants at the time when the convergence condition is satisfied. More specifically, which feature value should be extracted to establish correlation between the feature value and a full charge capacity Q of the module is confirmed in advance in experiments. More specifically, relation between a feature value F and full charge capacity Q (a full charge capacity measured by actual charging and discharging of the module) of a large number of (for example, several hundred to several thousand) modules is experimentally found. Feature value F(M) can be extracted from the eight circuit constants, for example, by a statistic approach such as multiple regression analysis.

When feature value F(M) is extracted from the eight circuit constants, processing system 200 calculates a full charge capacity Q(M) of module M based on extracted feature value F(M) by referring to correlation between feature value F and full charge capacity Q (S14).

Thereafter, processing system 200 determines a manner of recycle of module M in accordance with full charge capacity Q(M) of module M.

FIG. 9 is a diagram for illustrating one example of accuracy in estimation of a capacity of a module in Comparative Example 1. In FIG. 9 and FIGS. 11 and 15 which will be described later, the abscissa represents an actual full charge capacity of the module. The actual full charge capacity refers, for example, to a full charge capacity measured with a measurement approach generally regarded as highly accurate, although it requires time for measurement, such as measurement of an amount of charging in charging of a module from a completely discharged state to a fully charged state. This value is also denoted below as an “actually measured value of the full charge capacity.” The ordinate represents a full charge capacity of a module calculated in the previously-described capacity estimation processing in Comparative Example 1. This value is also denoted below as an “estimated value of the full charge capacity.”

FIGS. 9, 11, and 15 each show with a straight line L1 (a solid line), a state that the estimated value of the full charge capacity and the actually measured value of the full charge capacity exactly match with each other. A state that an error between the estimated value of the full charge capacity and the actually measured value of the full charge capacity is within a prescribed range (±0.5 Ah in this example) is shown as a range lying between two straight lines L2 (dashed lines) (which is denoted as a “matching range”). A ratio of the estimated value of the full charge capacity being within the matching range as a result of estimation of the full charge capacity of a large number of modules by capacity estimation processing is herein called “capacity estimation accuracy.”

In Comparative Example 1 to which the non-linear least squares method was applied, capacity estimation accuracy was 79.8%. Though this value is relatively large, a larger value (for example, a target value being at least 80%) can desirably be achieved. This may be because feature value F(M) could not precisely be extracted from impedance curve Z represented by combination of at most several to more than ten (eight in this example) circuit constants and hence there was a room for improvement in capacity estimation accuracy. Capacity estimation accuracy in application of another approach such as the genetic algorithm was lower than capacity estimation accuracy in application of the non-linear least squares method.

<Capacity Estimation Processing in Comparative Example 2>

In capacity estimation processing in Comparative Example 2, a neural network model was used for estimating a full charge capacity of a module. In the neural network model, machine learning by the network was performed so as to output a result of highly accurate estimation of the full charge capacity from an output layer when a result of measurement of an AC impedance was given to an input layer.

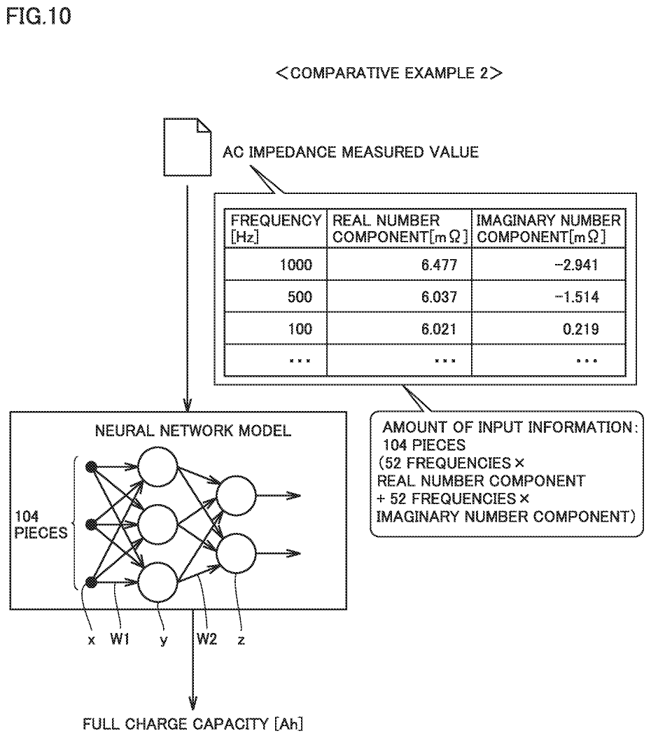

FIG. 10 is a conceptual diagram for illustrating training of a neural network in Comparative Example 2. Referring to FIG. 10, a neural network model includes, for example, an input layer x, a hidden layer y, and an output layer z. A weight between input layer x and the hidden layer is denoted as W1 and a weight between hidden layer y and output layer z is denoted as W2.

What is given to input layer x of the neural network model in Comparative Example 2 is numeric data representing a result of measurement of the AC impedance of a module. More specifically, combination (f, Z_{Re}) of a frequency of an application signal and a real number component of the AC impedance and combination (f, Z_{Im}) of the frequency of the application signal and an imaginary number component of the AC impedance are given to input layer x. In the example of measurement of the AC impedance shown in FIG. 6, signals at 52 frequencies in a frequency region from 100 mHz to 1 kHz are applied. In this case, 104 pieces of numeric data which are the sum of the number of real number components and the number of imaginary number components from results of measurement of the AC impedance of one module are given to input layer x. Therefore, input layer x includes 104 nodes. Output layer z can include, for example, 71 nodes so as to be able to output results of estimation of the full charge capacity in increments of 0.1 Ah within a range from 0 Ah to 7 Ah.

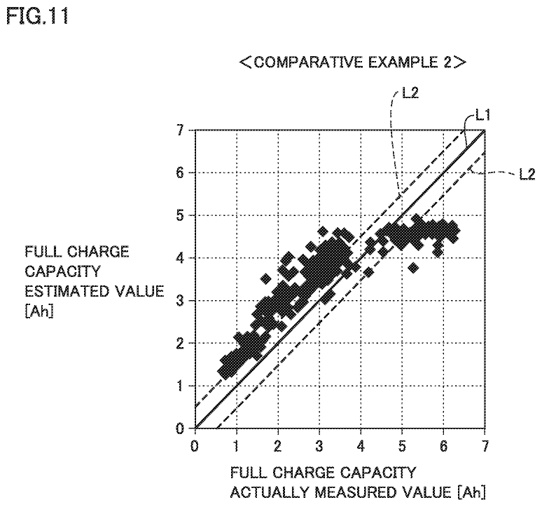

FIG. 11 is a diagram for illustrating one example of accuracy in estimation of a capacity of a module in Comparative Example 2. As shown in FIG. 11, it can be seen that many of plots of combination of the estimated value and the actually measured value of the full charge capacity are outside the matching range lying between two straight lines L2. Specifically, in Comparative Example 2 to which a general approach of the neural network model is applied, capacity estimation accuracy was 17.8%. Namely, Comparative Example 2 was rather lower in capacity estimation accuracy than Comparative Example 1.

In general, training of a neural network model has been evaluated as an approach suitable for extraction of a feature value. In Comparative Example 2, however, sufficient capacity estimation accuracy was not achieved in spite of training of the neural network. The present inventors assumed reasons therefor as an insufficient amount of information (an amount of input information) given to input layer x. Namely, the present inventors assumed that, though 104 pieces of numeric data were given to the input layer for each module of which AC impedance was measured in Comparative Example 2 as described previously, the amount of input information might have been insufficient for training of the neural network model.

Then, in the present embodiment, in order to increase an amount of input information, instead of numeric data representing a Nyquist plot, data of an image in which a Nyquist plot is drawn (numeric data for each pixel in the image) is given to input layer x as input information.

<Capacity Estimation Processing in Present Embodiment>

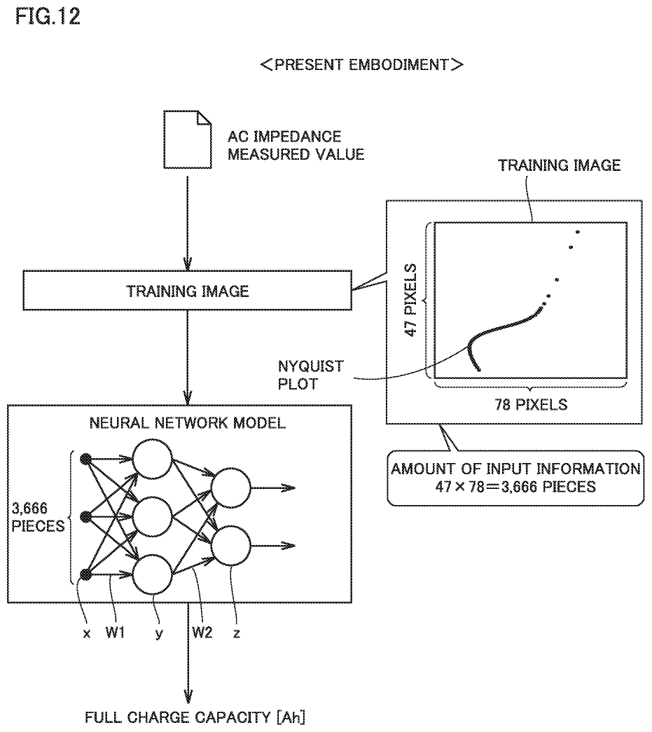

FIG. 12 is a conceptual diagram for illustrating machine learning by a neural network model in the present embodiment. Referring to FIG. 12, in the present embodiment, an image is generated based on a result of measurement of the AC impedance of a module (Nyquist plot). This image is also referred to as a “training image” below. The training image is generated for each result of measurement of the AC impedance. When the AC impedance of m modules is measured, m training images are generated. Such a large number of training images are successively given to input layer x of the neural network model and used for machine learning by the neural network model.

For example, in the example shown in FIG. 6, when the AC impedance of one certain module is measured, results of measurement of the AC impedance at 52 frequencies are obtained. In Comparative Example 2, however, only 104 pieces of numeric data originating from the results of measurement of the AC impedance at 52 frequencies can be obtained as input information.

In contrast, the training image in the present embodiment is made up of a region of vertical 47 pixels×horizontal 78 pixels=3,666 pixels as shown in FIG. 12. In the training image, a pixel which matches with any of results of measurement of the AC impedance (Nyquist plot) at 52 frequencies is black-colored, and a pixel which matches with none of them is white-colored. By doing so, 3,666 pieces of input information can be obtained from the results of measurement of the AC impedance at 52 frequencies. Since the training image contains not only information represented by the pixels which match with the Nyquist plot but also information represented by the pixels which do not match with the Nyquist plot, an amount of input information is large. Input layer x of the neural network model includes 3,666 nodes in correspondence with 3,666 pieces of input information.

Thus, in the present embodiment, a training image including a large number of (for example, several thousand to several hundred thousand) pixels is generated from a result of measurement of the AC impedance of each module. In the training image, color data resulting from binary processing into black and white (monochrome data) is defined for each pixel. By using such a training image, an amount of input information for expressing a difference in characteristic (full charge capacity) between one module and another module is increased. Capacity estimation accuracy can thus be higher than in Comparative Example 2 (which will be described later).

FIG. 13 is a flowchart showing a method of training a neural network model in the present embodiment. Referring to FIG. 13, in S31, an untrained neural network model is prepared. In the example described previously, input layer x includes 3666 nodes. Output layer z includes 71 nodes so as to be able to output results of estimation of the full charge capacity in increments of 0.1 Ah within a range from 0 Ah to 7 Ah.

In S32, training images as many as results of measurement of the AC impedance of a large number of modules are generated. Since this processing is described in detail with reference to FIG. 12, description will not be repeated.

In S33, processing system 200 inputs any training image (any of images generated in S31) to input layer x of the neural network model and performs supervised learning for estimating a full charge capacity of the module from the training image. More specifically, training is performed in a procedure as below.

Initially, whether or not an estimated value of the full charge capacity is correct is determined based on comparison between the estimated value of the full charge capacity and the actually measured value of the full charge capacity and whether or not the estimated value is correct is fed back as a teaching signal. For example, it is assumed that the full charge capacity of a certain module is estimated as Qk from the training image of the module. When the actually measured value of the full charge capacity of that module is Qk, the teaching signal indicating that estimation was correct is fed back. On the other hand, when the actually measured value of the full charge capacity of that module is not Qk, the fact that estimation is incorrect is fed back as a teaching signal. In accordance with the teaching signal based on results of estimation of a large number of modules, weight W1 between input layer x and hidden layer y and weight W2 between hidden layer y and output layer z are adjusted. By thus repeating correction by the teaching signal while estimation using a large number of training images is being made, capacity estimation accuracy of the neural network model is enhanced. When capacity estimation accuracy is higher than a prescribed value or a prescribed time period has elapsed, processing in S33 ends. Training of the neural network model is thus completed.

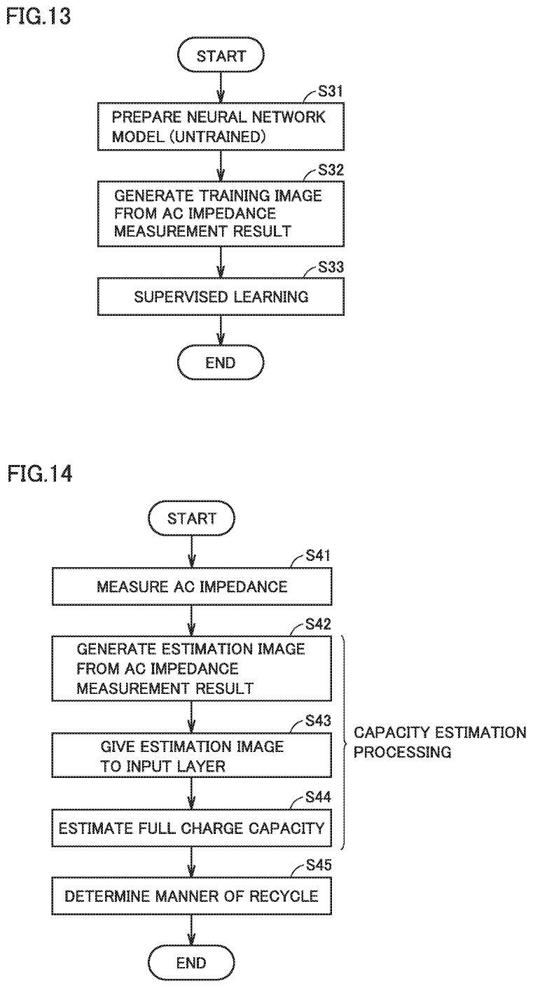

FIG. 14 is a flowchart showing processing for estimating a capacity of module M in the present embodiment. Processing in S42 to S44 below corresponds to processing for estimating a capacity of module M.

Referring to FIG. 14. processing system 200 initially measures the AC impedance of module M (S41). Then, processing system 200 generates an image for estimating the full charge capacity of module M (which is denoted as an “estimation image”) from a result of measurement of the AC impedance of module M (S42). An approach to generation of an estimation image is similar to the approach to generation of a training image described with reference to FIG. 13.

In S43, processing system 200 gives the estimation image generated in S42 to input layer x of the trained neural network model.

In S44, processing system 200 receives an estimated value of the full charge capacity of module M from output layer z of the neural network model.

In S45, processing system 200 determines a manner of recycle of module M based on the estimated value of the full charge capacity of module M. For example, processing system 200 calculates a ratio (=Q(M)/Q0) between current full charge capacity Q(M) representing the estimated value of the full charge capacity of module M and an initial full charge capacity Q0 (a value already known based on specifications of module M) as a “capacity retention,” and compares the capacity retention with a prescribed reference value. When the capacity retention of module M is equal to or higher than the reference value, processing system 200 determines that module M can be used for rebuilding a battery assembly, and when the capacity retention of module M is lower than the reference value, it determines that module M cannot be used for rebuild (should be resource-recycled).

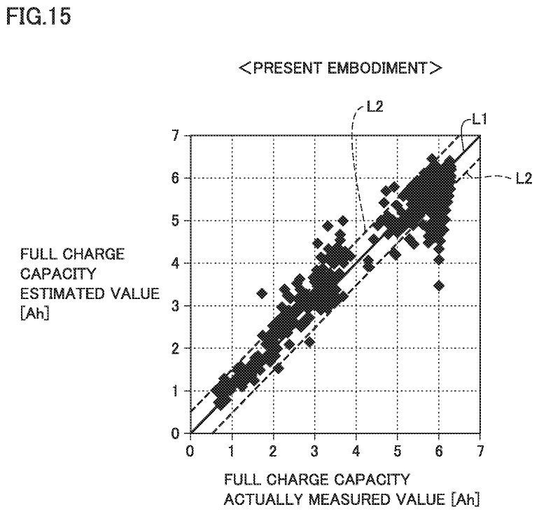

FIG. 15 is a diagram for illustrating one example of accuracy in estimation of a capacity of a module in the present embodiment and is compared with FIG. 11. A sufficiently high ratio of plots located in the matching range among plots of combination of the estimated value and the actually measured value of the full charge capacity can be seen in FIG. 15. Capacity estimation accuracy in the present embodiment was 83.0%. This value is highest as compared with capacity estimation accuracy (17.8%) in Comparative Example 2 and capacity estimation accuracy (79.8%) in Comparative Example 1. It can thus be concluded that improvement in capacity estimation accuracy in the present embodiment is supported.

As set forth above, in the present embodiment, machine learning by the neural network model is achieved by giving a training image which is image data (numeric data for each pixel in an image) representing a Nyquist plot to input layer x as input information. Thus, as compared with Comparative Example 2 in which numeric data of a result of measurement of the AC impedance of a module is used as it is, an amount of information given to input layer x (an amount of input information) significantly increases. Since this means increase in input of information which can express a difference in full charge capacity between one module and another module, high-precision training of the neural network model can be realized. Consequently, according to the present embodiment, accuracy in estimation of the full charge capacity of module M can be improved. According to the present embodiment, a battery assembly can be manufactured from a module of which full charge capacity has highly accurately been estimated.

Though the embodiment of the present disclosure has been described, it should be understood that the embodiment disclosed herein is illustrative and non-restrictive in every respect. The scope of the present disclosure is defined by the terms of the claims and is intended to include any modifications within the scope and meaning equivalent to the terms of the claims.

What is claimed is:

1. A battery information processing system which processes information for estimating a full charge capacity of a secondary battery, the battery information processing system comprising:
a storage device configured to store a trained neural network model; and
an estimation device configured to estimate a full charge capacity of the secondary battery from a result of measurement of an AC impedance of the secondary battery by using the trained neural network model,
the trained neural network model including an input layer given a numeric value for each pixel of an image in which a Nyquist plot is drawn in a region consisting of a predetermined number of pixels, the Nyquist plot representing the result of measurement of the AC impedance of the secondary battery.

2. The battery information processing system according to claim 1, wherein
the predetermined number of pixels is greater than a sum of the number of real number components and the number of imaginary number components both representing the result of measurement of the AC impedance of the secondary battery.

3. The battery information processing system according to claim 1, wherein
the result of measurement of the AC impedance of the secondary battery includes a result of measurement of the AC impedance when a frequency of an applied AC signal is within a frequency range not lower than 100 mHz and not higher than 1 kHz.

4. A battery assembly comprising:
a plurality of the secondary batteries of which full charge capacity has been estimated by the battery information processing system according to claim 1.

5. A method of estimating a capacity of a secondary battery comprising:
obtaining a result of measurement of an AC impedance of the secondary battery; and
estimating a full charge capacity of the secondary battery from the result of measurement of the AC impedance of the secondary battery by using a trained neural network model,
the trained neural network model including an input layer given a numeric value for each pixel of an image in which a Nyquist plot is drawn in a region consisting of a predetermined number of pixels, the Nyquist plot representing the result of measurement of the AC impedance of the secondary battery.

6. A method of manufacturing a battery assembly comprising:
obtaining a result of measurement of an AC impedance of a secondary battery;
estimating a full charge capacity of the secondary battery from the result of measurement of the AC impedance of the secondary battery by using a trained neural network model; and
manufacturing a battery assembly from a plurality of the secondary batteries of which full charge capacity has been estimated in the estimating a full charge capacity,
the trained neural network model including an input layer given a numeric value for each pixel of an image in which a Nyquist plot is drawn in a region consisting of a predetermined number of pixels, the Nyquist plot representing the result of measurement of the AC impedance of the secondary battery.
